(19) United States
(12) Patent Application Publication
(10) Pub. No.: US 2024/0146258 A1
(43) Pub. Date: May 2, 2024

(54) POWER AMPLIFIER CIRCUIT AND POWER AMPLIFICATION METHOD

(71) Applicant: Murata Manufacturing Co., Ltd., Nagaokakyo-shi (JP)

(72) Inventors: Kenji TAHARA, Nagaokakyo-shi (JP); Shigeru TSUCHIDA, Nagaokakyo-shi (JP); Kae YAMAMOTO, Nagaokakyo-shi (JP)

(73) Assignee: Murata Manufacturing Co., Ltd., Nagaokakyo-shi (JP)

(21) Appl. No.: 18/407,467

(22) Filed: Jan. 9, 2024

Related U.S. Application Data
(63) Continuation of application No. PCT/JP2022/022748, filed on Jun. 6, 2022.

(30) Foreign Application Priority Data
Jul. 14, 2021 (JP) 2021-116276

(51) Int. Cl. H03F 3/24; H03F 1/56; H03F 3/195; H03F 3/72

(52) U.S. Cl. CPC H03F 3/245; H03F 1/565; H03F 3/195; H03F 3/72; H03F 2200/423; H03F 2200/451; H03F 2200/537; H03F 2203/7206

(57) ABSTRACT

A power amplifier circuit that includes an external input terminal and an external output terminal; a first power amplifier, a second power amplifier, a third power amplifier, and a fourth power amplifier; a transformer including an input-side coil and an output-side coil; and a first transmission line, the external input terminal being connected to an input terminal of the first and second power amplifiers, an output terminal of the first power amplifier is connected to an input terminal of the third and fourth power amplifiers, output terminals of the third and fourth power amplifiers being connected to a first and second end of the input-side coil respectively, the external output terminal being connected to a first end of the output-side coil, and an output terminal of the second power amplifier being connected to a second end of the output-side coil via the first transmission line.

### CROSS-REFERENCE TO RELATED APPLICATIONS

The present application is a continuation of PCT application PCT/JP2022/022748, filed Jun. 6, 2022, and claims priority to Japanese application JP 2021-116276, filed Jul. 14, 2021, the entire contents of each of which being incorporated herein by reference.

### TECHNICAL FIELD

The present disclosure relates to a power amplifier circuit and a power amplification method.

### BACKGROUND ART

Patent Document 1 discloses a power amplifier circuit including a first amplifier the input of which is connected to a first signal input terminal, a second amplifier the input of which is connected to a second signal input terminal, and an amplifier output phase shifter the input of which is connected to the output of the first amplifier and the output of which is connected to the output of the second amplifier. The power amplifier circuit further includes a transformer including a primary coil one end of which is connected to a power supply and another end of which is connected to the output of the amplifier output phase shifter, and a secondary coil one end of which is connected to a first signal output terminal and another end of which is connected to a second signal output terminal.

### CITATION LIST

Patent Document
Patent Document 1: Japanese Unexamined Patent Application Publication No. 2013-085179

### SUMMARY

### Technical Problems

However, when multiple power amplifiers connected to a transformer are used as an output stage of a multi-stage amplifier circuit, the efficiency (the ratio of output power to power consumption) at relatively low output power may be reduced.

For the above reason, the present disclosure provides a power amplifier circuit and a power amplification method that can improve the efficiency at relatively low output power when multiple power amplifiers connected to a transformer are used as an output stage of a multi-stage amplifier circuit.

### Solution to Problem

According to an aspect of the present disclosure, a power amplifier circuit includes an external input terminal and an external output terminal; a first power amplifier, a second power amplifier, a third power amplifier, and a fourth power amplifier; a transformer including an input-side coil and an output-side coil; and a first transmission line. The external input terminal is connected to an input terminal of the first power amplifier and an input terminal of the second power amplifier; an output terminal of the first power amplifier is connected to an input terminal of the third power amplifier and an input terminal of the fourth power amplifier; an output terminal of the third power amplifier is connected to a first end of the input-side coil; an output terminal of the fourth power amplifier is connected to a second end of the input-side coil; the external output terminal is connected to a first end of the output-side coil; and an output terminal of the second power amplifier is connected to a second end of the output-side coil via the first transmission line.

According to an aspect of the present disclosure, a power amplification method has a first power mode corresponding to first output power and a second power mode corresponding to second output power lower than the first output power. The power amplification method includes: in the first power mode, controlling a first power amplifier, which is connected to an input-side coil of a transformer via a third power amplifier and a fourth power amplifier, to be in an ON state and controlling a second power amplifier, which is connected via a transmission line to an output-side coil of the transformer, to be in an OFF state; and in the second power mode, controlling the first power amplifier to be in the OFF state and controlling the second power amplifier to be in the ON state.

According to an aspect of the present disclosure, a power amplifier circuit includes an external input terminal and an external output terminal; a first power amplifier, a second power amplifier, a third power amplifier, and a fourth power amplifier; and a transformer including an input-side coil and an output-side coil. The external input terminal is connected to an input terminal of the first power amplifier and an input terminal of the second power amplifier; an output terminal of the first power amplifier is connected to an input terminal of the third power amplifier and an input terminal of the fourth power amplifier; an output terminal of the second power amplifier and an output terminal of the third power amplifier are connected to a first end of the input-side coil; an output terminal of the fourth power amplifier is connected to a second end of the input-side coil; a first end of the output-side coil is connected to the external output terminal; and a second end of the output-side coil is connected to a ground.

According to an aspect of the present disclosure, a power amplification method has a first power mode corresponding to first output power and a second power mode corresponding to second output power lower than the first output power. The power amplification method includes: in the first power mode, controlling a first power amplifier, which is connected to an input-side coil of a transformer via a third power amplifier and a fourth power amplifier, to be in an ON state and controlling a second power amplifier, which is connected to the input-side coil of the transformer not via the third power amplifier and the fourth power amplifier, to be in an OFF state; and in the second power mode, controlling the first power amplifier to be in the OFF state and controlling the second power amplifier to be in the ON state.

### Advantageous Effects

A power amplifier circuit according to an aspect of the present disclosure can improve the efficiency at relatively low output power when multiple power amplifiers connected to a transformer are used as an output stage of a multi-stage amplifier circuit.

### BRIEF DESCRIPTION OF DRAWINGS

FIG. 1 is a circuit diagram of a power amplifier circuit, a radio frequency circuit, and a communication device according to a first embodiment.

FIG. 2 is a circuit diagram of power amplifiers according to the first embodiment.

FIG. 3 is a circuit state diagram of the power amplifier circuit in a low power mode according to the first embodiment.

FIG. 4 is a circuit state diagram of the power amplifier circuit in a middle power mode according to the first embodiment.

FIG. 5 is a circuit state diagram of the power amplifier circuit in a high power mode according to the first embodiment.

FIG. 6 is a graph showing the relationship between the output power and the total current consumption of the power amplifier circuit in each power mode.

FIG. 7 is a plan view of a power amplifier module according to an example of the first embodiment.

FIG. 8 is a plan view of the power amplifier module according to the example of the first embodiment.

FIG. 9 is a cross-sectional view of the power amplifier module according to the example of the first embodiment.

FIG. 10 is a cross-sectional view of the power amplifier module according to the example of the first embodiment.

FIG. 11 is a cross-sectional view of the power amplifier module according to the example of the first embodiment.

FIG. 12A is a cross-sectional view of a wire according to the example of the first embodiment.

FIG. 12B is a cross-sectional view of a wire according to the example of the first embodiment.

FIG. 13 is a circuit diagram of a power amplifier circuit according to a second embodiment.

FIG. 14 is a circuit state diagram of the power amplifier circuit in a low power mode according to the second embodiment.

FIG. 15 is a circuit state diagram of the power amplifier circuit in a middle power mode according to the second embodiment.

FIG. 16 is a circuit state diagram of the power amplifier circuit in a high power mode according to the second embodiment.

FIG. 17 is a plan view of a power amplifier module according to an example of the second embodiment.

FIG. 18 is a plan view of the power amplifier module according to the example of the second embodiment.

FIG. 19 is a cross-sectional view of the power amplifier module according to the example of the second embodiment.

FIG. 20 is a cross-sectional view of the power amplifier module according to the example of the second embodiment.

FIG. 21 is a circuit diagram of a power amplifier circuit according to a variation of the first embodiment.

FIG. 22 is a circuit diagram of a power amplifier circuit according to a variation of the second embodiment.

### DESCRIPTION OF EMBODIMENTS

Embodiments of the present disclosure are described below with reference to the drawings. Each of the embodiments described below represents a general or specific example. Values, shapes, materials, components, and the layouts and connection configurations of the components described in the embodiments below are just examples and are not intended to limit the present disclosure.

Each of the drawings is a schematic diagram in which components are emphasized or omitted and the ratios between the components are adjusted to facilitate the understanding of the present disclosure. That is, components in each of the drawings are not necessarily illustrated accurately; and the shapes, the positional relationships, and the ratios of the components may differ from the actual shapes, positional relationships, and ratios. The same reference number is assigned to substantially the same components in the drawings, and repeated descriptions of those components may be omitted or simplified.

In each of the drawings below, an x-axis and a y-axis are orthogonal to each other in a plane that is parallel to the major surface of a module substrate. Specifically, when the module substrate has a rectangular shape in plan view, the x-axis is parallel to a first side of the module substrate, and the y-axis is parallel to a second side of the module substrate that is orthogonal to the first side. Also, a z-axis is perpendicular to the major surface of the module substrate, a positive z-axis direction indicates an upward direction, and a negative z-axis direction indicates a downward direction.

In circuit configurations of the present disclosure, “connected” not only indicates that circuit elements are directly connected to each other with a connection terminal and/or a wire conductor but also indicates that the circuit elements are electrically connected to each other via another circuit element. Also, “connected between A and B” indicates that a component is disposed between A and B and connected to both of A and B. Specifically, “connected between A and B” not only indicates that a component is connected in series with A and B in a path connecting A and B but also indicates that a component is connected in parallel with (in shunt connection with) A and B at a position between the path and a ground.

In layouts of components of the present disclosure, “plan view” indicates a view of an object that is orthographically projected onto an xy plane from the positive z-axis side. “A overlaps B in plan view” indicates that the region of A orthographically projected onto the xy plane overlaps the region of B orthographically projected onto the xy plane. “A is disposed between B and C” indicates that at least one of multiple line segments connecting given points in B and given points in C passes through A. Also, terms such as “parallel” and “perpendicular” indicating relationships between elements, terms such as “rectangular” indicating shapes of elements, and numerical ranges do not only indicate their exact meanings but may also indicate substantially equivalent ranges that differ by, for example, about a few percent.

### First Embodiment

First, a first embodiment is described.

### 1.1 Circuit Configurations of Communication Device 6, Radio Frequency Circuit 1, and Power Amplifier Circuit 10

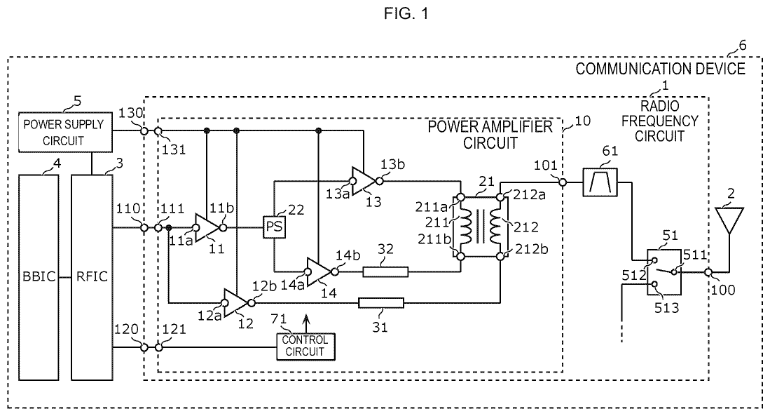

Circuit configurations of a communication device 6, a radio frequency circuit 1, and a power amplifier circuit 10 according to the present embodiment are described with reference to FIG. 1. FIG. 1 is a circuit diagram of the power amplifier circuit 10, the radio frequency circuit 1, and the communication device 6 according to the present embodiment.

### 1.1.1 Circuit Configuration of Communication Device 6

First, a circuit configuration of the communication device 6 is described. As illustrated in FIG. 1, the communication device 6 according to the present embodiment includes the radio frequency circuit 1, an antenna 2, a radio frequency integrated circuit (RFIC) 3, a baseband integrated circuit (BBIC) 4, and a power supply circuit 5.

The radio frequency circuit 1 transmits radio frequency signals between the antenna 2 and the RFIC 3. The internal configuration of the radio frequency circuit 1 is described later.

The antenna 2 is connected to an antenna connection terminal 100 of the radio frequency circuit 1 and transmits radio frequency signals output from the radio frequency circuit 1.

The RFIC 3 is an example of a signal processing circuit that processes radio frequency signals. Specifically, the RFIC 3 performs signal processing, such as down-converting, on a radio-frequency reception signal input via a reception path of the radio frequency circuit 1 and outputs a reception signal generated by the signal processing to the BBIC 4. Also, the RFIC 3 performs signal processing, such as up-converting, on a transmission signal from the BBIC 4 and outputs a radio frequency transmission signal generated by the signal processing to a transmission path of the radio frequency circuit 1. The RFIC 3 includes a control unit that controls the radio frequency circuit 1 and the power supply circuit 5. Some or all of the functions of the control unit of the RFIC 3 may be provided outside of the RFIC 3 and may be implemented by, for example, a component in the BBIC 4 or the radio frequency circuit 1.

The BBIC 4 is a baseband signal processing circuit that performs signal processing using an intermediate frequency band that is lower than the frequency of radio frequency signals transmitted by the radio frequency circuit 1. For example, a signal processed by the BBIC 4 is used as an image signal for displaying an image and/or a voice signal for a call via a speaker.

The power supply circuit 5 is capable of supplying a power-supply voltage to the power amplifier circuit 10. For example, the power supply circuit 5 may be a tracker capable of providing a power-supply voltage for tracking an envelope of a radio frequency signal. Examples of tracking methods include, but are not limited to, envelope tracking (ET) and average power tracking (APT). The power supply circuit 5 is not limited to a tracker and may be configured to supply a fixed power-supply voltage.

The circuit configuration of the communication device 6 is not limited to the example illustrated in FIG. 1. As another example, the communication device 6 may have a configuration not including the antenna 2 and/or the BBIC 4. As still another example, the communication device 6 may include multiple antennas.

### 1.1.2 Circuit Configuration of Radio Frequency Circuit 1

Next, a circuit configuration of the radio frequency circuit 1 is described. As illustrated in FIG. 1, the radio frequency circuit 1 includes the power amplifier circuit 10, a switch 51, a filter 61, an antenna connection terminal 100, an external input terminal 110, a control terminal 120, and a supply terminal 130. Components of the radio frequency circuit 1 are described in sequence below.

The antenna connection terminal 100 is connected to the switch 51 at a position inside of the radio frequency circuit 1 and is connected to the antenna 2 at a position outside of the radio frequency circuit 1. A radio frequency signal amplified by the power amplifier circuit 10 is output to the antenna 2 via the antenna connection terminal 100.

The external input terminal 110 receives a radio frequency signal from the outside of the radio frequency circuit 1. The external input terminal 110 is connected to the RFIC 3 at a position outside of the radio frequency circuit 1 and is connected to the power amplifier circuit 10 at a position inside of the radio frequency circuit 1. With this configuration, a radio frequency signal received from the RFIC 3 via the external input terminal 110 is supplied to the power amplifier circuit 10.

The control terminal 120 is for transmitting control signals. That is, the control terminal 120 receives control signals from the outside of the radio frequency circuit 1 and/or supplies control signals to the outside of the radio frequency circuit 1. The control signals are used to control electronic circuits included in the radio frequency circuit 1. Specifically, the control signals are, for example, digital signals for controlling power amplifiers 11 to 14.

The supply terminal 130 receives a power-supply voltage from the power supply circuit 5. The supply terminal 130 is connected to the power supply circuit 5 at a position outside of the radio frequency circuit 1 and is connected to the power amplifier circuit 10 at a position inside of the radio frequency circuit 1. With this configuration, the power-supply voltage received from the power supply circuit 5 via the supply terminal 130 is supplied to the power amplifier circuit 10.

The power amplifier circuit 10 is capable of amplifying radio frequency signals. The internal configuration of the power amplifier circuit 10 is described later.

The switch 51 is connected between the antenna connection terminal 100 and the filter 61. The switch 51 includes terminals 511 to 513. The terminal 511 is connected to the antenna connection terminal 100. The terminal 512 is connected to the filter 61. The terminal 513 is connected to a filter (not shown) that has a pass band different from the pass band of the filter 61. The terminal 513 need not necessarily be connected to a filter.

With this connection configuration, for example, the switch 51 can connect the terminal 511 to one or both of the terminals 512 and 513 based on a control signal from the RFIC 3. The switch 51 is implemented by, for example, a multi-connection switch circuit.

The filter 61 is connected between the power amplifier circuit 10 and the antenna connection terminal 100. Specifically, one end of the filter 61 is connected to the power amplifier circuit 10, and another end of the filter 61 is connected to the antenna connection terminal 100 via the switch 51. The filter 61 has a pass band that includes at least a part of a predetermined band. When the duplex mode of the predetermined band is Frequency Division Duplex (FDD), the filter 61 has a pass band including an uplink operating band that is a part of the predetermined band. As another example, when the duplex mode of the predetermined band is Time Division Duplex (TDD), the filter 61 may have a pass band that includes the entire predetermined band. With this configuration, the filter 61 can pass a transmission signal in the predetermined band among transmission signals amplified by the power amplifier circuit 10.

The predetermined band is a frequency band for a communication system that is constructed using radio access technology (RAT). The predetermined band is predefined by, for example, a standardization organization (e.g., the 3rd Generation Partnership Project (3GPP) (registered trademark) or the Institute of Electrical and Electronics Engineers (IEEE)). Examples of communication systems include a 5G NR system, a Long Term Evolution (LTE) system, and a wireless local area network (WLAN) system.

The configuration of the radio frequency circuit 1 is not limited to the example illustrated in FIG. 1. As another example, the radio frequency circuit 1 may be configured to not include the switch 51. As another example, the radio frequency circuit 1 may include a reception path. As still another example, the radio frequency circuit 1 may include three or more filters. In this case, the switch 51 may include four or more terminals.

### 1.1.3 Circuit Configuration of Power Amplifier Circuit 10

Next, a circuit configuration of the power amplifier circuit 10 is described. As illustrated in FIG. 1, the power amplifier circuit 10 includes power amplifiers (PA) 11 to 14, a transformer 21, a phase shifter (PS) 22, transmission lines 31 and 32, a control circuit 71, an external output terminal 101, an external input terminal 111, a control terminal 121, and a supply terminal 131. Below, components of the power amplifier circuit 10 are described in sequence.

The external input terminal 111 receives a transmission signal in the predetermined band from the outside of the power amplifier circuit 10. The external input terminal 111 is connected to the RFIC 3 via the external input terminal 110 at a position outside of the power amplifier circuit 10, and is connected to an input terminal 11a of the power amplifier 11 and an input terminal 12a of the power amplifier 12 at positions inside of the power amplifier circuit 10. With this configuration, a transmission signal in the predetermined band received from the RFIC 3 via the external input terminal 111 is supplied to the power amplifiers 11 and 12. The external input terminal 111 may be integrated with the external input terminal 110.

The control terminal 121 is for transmitting control signals. That is, the control terminal 121 receives a control signal from the outside of the power amplifier circuit 10 and/or supplies a control signal to the outside of the power amplifier circuit 10. The control terminal 121 may be integrated with the control terminal 120.

The supply terminal 131 receives a power-supply voltage from the power supply circuit 5. The supply terminal 131 is connected to the power supply circuit 5 via the supply terminal 130 at a position outside of the power amplifier circuit 10 and is connected to the power amplifiers 11 to 14 at positions inside of the power amplifier circuit 10. With this configuration, the power-supply voltage received from the power supply circuit 5 via the supply terminal 131 is supplied to the power amplifiers 11 to 14. The supply terminal 131 may be integrated with the supply terminal 130.

The power amplifier 11 is an example of a first power amplifier and is connected between the external input terminal 111 and the external output terminal 101. Specifically, the input terminal 11a of the power amplifier 11 is connected to the external input terminal 111. An output terminal 11b of the power amplifier 11 is connected to an input terminal 13a of the power amplifier 13 and an input terminal 14a of the power amplifier 14 via the phase shifter 22. That is, the power amplifier 11 is connected to an input-side coil 211 of the transformer 21 via the power amplifiers 13 and 14.

With this connection configuration, the power amplifier 11 can amplify a transmission signal in the predetermined band received via the external input terminal 111 by using the power-supply voltage supplied via the supply terminal 131. The transmission signal amplified by the power amplifier 11 is supplied to the power amplifiers 13 and 14 via the phase shifter 22. The power amplifier 11 corresponds to an input stage (or a drive stage) of a multi-stage amplifier circuit and constitutes the multi-stage amplifier circuit together with the power amplifiers 13 and 14.

The power amplifier 12 is an example of a second power amplifier and is connected between the external input terminal 111 and the transformer 21. Specifically, the input terminal 12a of the power amplifier 12 is connected to the external input terminal 111. An output terminal 12b of the power amplifier 12 is connected to an output-side coil 212 of the transformer 21 via the transmission line 31. That is, the power amplifier 12 is connected to the output-side coil 212 of the transformer 21 not via the power amplifiers 13 and 14.

With this connection configuration, the power amplifier 12 can amplify a transmission signal in the predetermined band received via the external input terminal 111 by using the power-supply voltage supplied via the supply terminal 131. The transmission signal amplified by the power amplifier 12 is supplied to the external output terminal 101 via the transmission line 31 and the transformer 21.

The phase shifter 22 is connected between the power amplifier 11 and the power amplifiers 13 and 14. Specifically, an input end of the phase shifter 22 is connected to the output terminal 11b of the power amplifier 11, and two output ends of the phase shifter 22 are connected to the input terminal 13a of the power amplifier 13 and the input terminal 14a of the power amplifier 14.

With this connection configuration, the phase shifter 22 can split the signal amplified by the power amplifier 11 into two split signals and output the split signals to the corresponding power amplifiers 13 and 14. Also, the phase shifter 22 can adjust the phases of the two split signals. For example, the phase shifter 22 can shift a signal to be input to the power amplifier 14 by −90 degrees (or delay the signal by 90 degrees) with respect to a signal to be input to the power amplifier 13. The phase adjustment performed by the phase shifter 22 is not limited to the above example. As another example, the phase shifter 22 may appropriately change the phase difference between the two split signals based on the internal configuration of the power amplifier circuit 10.

The power amplifier 13 is an example of a third power amplifier and is connected between the power amplifier 11 and the transformer 21. Specifically, the input terminal 13a of the power amplifier 13 is connected to the output terminal 11b of the power amplifier 11 via the phase shifter 22. The output terminal 13b of the power amplifier 13 is connected to the input-side coil 211 of the transformer 21.

With this connection configuration, the power amplifier 13 can amplify a transmission signal that is in the predetermined band and amplified by the power amplifier 11 by using the power-supply voltage supplied via the supply terminal 131. For example, the power amplifier 13 is implemented by a class AB amplifier and functions as a carrier amplifier of a Doherty amplifier. Also, the power amplifier 13 and the power amplifier 12 correspond to an output stage (or a power stage) of a multi-stage amplifier circuit.

The power amplifier 14 is an example of a fourth power amplifier and is connected between the power amplifier 11 and the transformer 21. Specifically, the input terminal 14a of the power amplifier 14 is connected to the output terminal 11b of the power amplifier 11 via the phase shifter 22. The output terminal 14b of the power amplifier 14 is connected to the transformer 21 via the transmission line 32.

With this connection configuration, the power amplifier 14 can amplify a transmission signal that is in the predetermined band and amplified by the power amplifier 11 by using the power-supply voltage supplied via the supply terminal 131. For example, the power amplifier 14 is implemented by a class C amplifier and functions as a peak amplifier of a Doherty amplifier. Also, the power amplifier 14 and the power amplifier 11 correspond to an output stage (or a power stage) of a multi-stage amplifier circuit.

As described above, the power amplifiers 13 and 14 are connected to the corresponding ends (211a and 211b) of the input-side coil 211 of the transformer 21. That is, the power amplifiers 13 and 14 are connected in parallel with each other.

A Doherty amplifier achieves high efficiency by combining multiple different types of amplifiers (for example, a class A amplifier (including a class AB amplifier) and a class C amplifier). With a Doherty amplifier, the load impedance seen from a carrier amplifier varies depending on the output power level, and the efficiency at a low power level is improved.

A carrier amplifier in a Doherty amplifier operates regardless of whether the power of a radio frequency signal (or an input) is low or high. Also, a peak amplifier in a Doherty amplifier operates only when the power of a radio frequency signal (or an input) is high. Accordingly, when the input power of a radio frequency signal is low, the radio frequency signal is amplified by the carrier amplifier; and when the input power of a radio frequency signal is high, the radio frequency signal is amplified by the carrier amplifier and the peak amplifier, and the amplified signals are combined. The carrier amplifier may be implemented by, for example, a class A amplifier (including a class AB amplifier), and the peak amplifier may be implemented by, for example, a class C amplifier.

The transmission line 31 is an example of a first transmission line and can rotate the load impedance by 180 degrees on the Smith chart. For example, the transmission line 31 may be implemented by a ¼ wavelength transmission line. The length of the transmission line 31 is determined based on the predetermined band. The transmission line 31 may also be referred to as a phase adjuster or a phase shifter.

The transmission line 31 is connected between the power amplifier 12 and the transformer 21. Specifically, one end of the transmission line 31 is connected to the output terminal 12b of the power amplifier 12, and another end of the transmission line 31 is connected to the output-side coil 212 of the transformer 21. With this connection configuration, the transmission line 31 can shift the phase of a transmission signal, which has been amplified by the power amplifier 12 and is in the predetermined band, by −90 degrees (or delay the phase of the transmission signal by 90 degrees).

The transmission line 32 is an example of a second transmission line and can rotate the load impedance by 180 degrees on the Smith chart. For example, the transmission line 32 may be implemented by a ¼ wavelength transmission line. The length of the transmission line 32 is determined based on the predetermined band. The transmission line 32 may also be referred to as a phase adjuster or a phase shifter.

The transmission line 32 is connected between the power amplifier 14 and the transformer 21. Specifically, one end of the transmission line 32 is connected to the output terminal 14b of the power amplifier 14, and another end of the transmission line 32 is connected to the input-side coil 211 of the transformer 21. With this connection configuration, the transmission line 32 can shift the phase of a transmission signal, which has been amplified by the power amplifier 14 and is in the predetermined band, by −90 degrees (or delay the phase of the transmission signal by 90 degrees).

The transmission line 31 and/or the transmission line 32 may include at least one of an inductor and a capacitor. For example, the transmission line 31 and/or the transmission line 32 may include one or more inductors and/or capacitors connected in series to a path that connects the power amplifier 12 to the transformer 21 and may include one or more inductors and/or capacitors connected between the path and a ground. This configuration makes it possible to shorten the length of the transmission line 31 and/or the transmission line 32.

The transformer 21 includes the input-side coil 211 and the output-side coil 212. A first end 211a of the input-side coil 211 is connected to the output terminal 13b of the power amplifier 13, and a second end 211b of the input-side coil 211 is connected to the output terminal 14b of the power amplifier 14 via the transmission line 32. A first end 212a of the output-side coil 212 is connected to the external output terminal 101, and a second end 212b of the output-side coil 212 is connected to the output terminal 12b of the power amplifier 12 via the transmission line 31.

With this connection configuration, the transformer 21 can combine transmission signals amplified by the power amplifiers 13 and 14 and output the resulting signal to the external output terminal 101. Also, the transformer 21 can output a transmission signal amplified by the power amplifier 12 to the external output terminal 101.

The external output terminal 101 supplies a transmission signal, which is in the predetermined band and amplified by the power amplifier circuit 10, to the outside of the power amplifier circuit 10. The external output terminal 101 is connected to the output-side coil 212 of the transformer 21 at a position inside of the power amplifier circuit 10 and is connected to the filter 61 at a position outside of the power amplifier circuit 10. With this configuration, the transmission signal supplied via the external output terminal 101 is transmitted to the antenna connection terminal 100 via the filter 61.

The control circuit 71 has multiple power modes and controls the power amplifiers 11 to 14 according to the multiple power modes. The multiple power modes include at least a low power mode and further include a high power mode and/or a middle power mode.

The high power mode and/or the middle power mode are examples of a first power mode and correspond to high output power and middle output power that is lower than the high output power. The low power mode is an example of a second power mode and corresponds to low output power that is lower than the high output power and the middle output power. That is, the high power mode and/or the middle power mode correspond to first output power (the high output power and the middle output power), and the low power mode corresponds to second output power (the low output power) that is lower than the first output power. Operations of the power amplifier circuit 10 in respective power modes are described later with reference to FIGS. 3 to 5.

The control circuit 71 may also control other circuit components (for example, the switch 51). Also, a part or the entirety of the control circuit 71 may be provided outside of the power amplifier circuit 10 and may be included in the radio frequency circuit 1.

The circuit configuration of the power amplifier circuit 10 is not limited to the example illustrated in FIG. 1. For example, the power amplifier circuit 10 may be a differential summing amplifier circuit instead of a Doherty amplifier. In this case, the power amplifier circuit 10 need not include the transmission line 32. Also, for example, a transformer that splits a signal into two signals with a phase difference of 180 degrees may be used as the phase shifter 22.

### 1.1.4 Circuit Configurations of Power Amplifiers 11 and 12

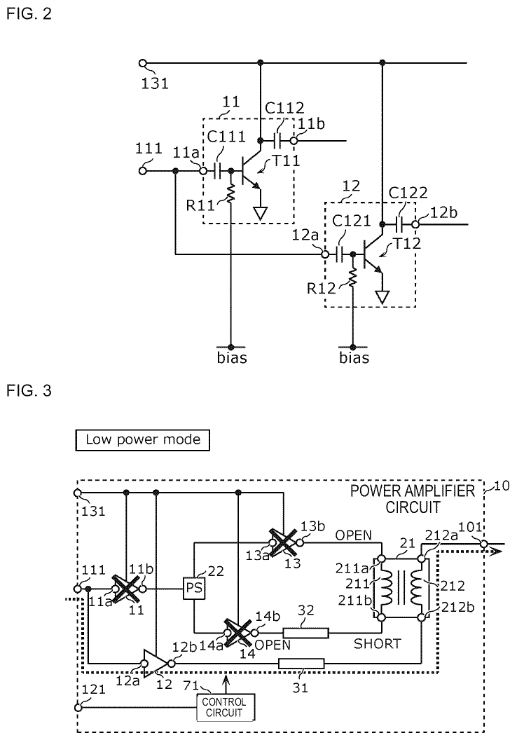

Next, circuit configurations of the power amplifiers 11 and 12 are described with reference to FIG. 2. FIG. 2 is a circuit diagram of the power amplifiers 11 and 12 according to the present embodiment.

As illustrated in FIG. 2, the power amplifier 11 includes an amplifier transistor T11, capacitors C111 and C112, and a resistor R11. The emitter terminal of the amplifier transistor T11 is connected to the ground. The base terminal of the amplifier transistor T11 is connected to the input terminal 11a via the capacitor C111 and is also connected to a bias source (not shown) via the resistor R11. The collector terminal of the amplifier transistor T11 is connected to the supply terminal 131 and is also connected to the output terminal 11b via the capacitor C112. The power amplifier 11 can be switched between an ON state and an OFF state by a bias signal supplied from the bias source.

Also, as illustrated in FIG. 2, the power amplifier 12 includes an amplifier transistor T12, capacitors C121 and C122, and a resistor R12. The emitter terminal of the amplifier transistor T12 is connected to the ground. The base terminal of the amplifier transistor T12 is connected to the input terminal 12a via the capacitor C121 and also connected to a bias source (not shown) via the resistor R12. The collector terminal of the amplifier transistor T12 is connected to the supply terminal 131 and is also connected to the output terminal 12b via the capacitor C122. The power amplifier 12 can be switched between an ON state and an OFF state by a bias signal supplied from the bias source.

The circuit configurations of the power amplifiers 11 and 12 are not limited to the examples illustrated in FIG. 2. For example, the amplifier transistors T11 and T12 are not limited to bipolar transistors illustrated in FIG. 2. For example, one or each of the amplifier transistors T11 and T12 may be implemented by a field effect transistor. In this case, “emitter”, “base”, and “collector” described above are replaced with “source”, “gate”, and “drain”, respectively. Also, for example, the emitter terminal of at least one of the amplifier transistors T11 and T12 may be connected to the ground via an inductor (not shown). The drain terminal of at least one of the amplifier transistors T11 and T12 may be connected to the supply terminal 131 via an inductor (not shown). Also, a capacitor (not shown) may be connected between the base and the emitter of at least one of the amplifier transistors T11 and T12. Furthermore, the base terminal of the amplifier transistor T12 may be connected to the input terminal 11a via a resistor (not shown).

### 1.2 Operations of Power Amplifier Circuit 10

Next, operations of the power amplifier circuit 10 according to the present embodiment are described.

### 1.2.1 Flow of Radio Frequency Signal in Each Power Mode

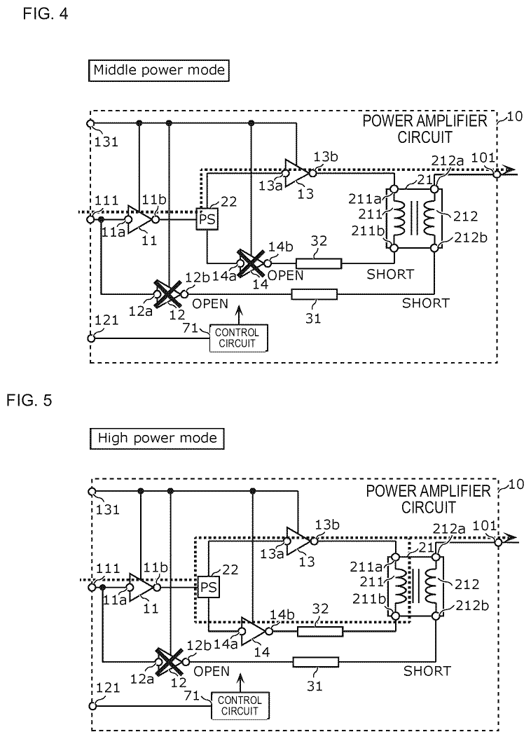

First, the flow of a radio frequency signal in each power mode is described with reference to FIGS. 3 to 5. FIG. 3 is a circuit state diagram of the power amplifier circuit 10 in the low power mode according to the present embodiment. FIG. 4 is a circuit state diagram of the power amplifier circuit 10 in the middle power mode according to the present embodiment. FIG. 5 is a circuit state diagram of the power amplifier circuit 10 in the high power mode according to the present embodiment.

In the low power mode, as illustrated in FIG. 3, the power amplifiers 11, 13, and 14 do not operate (in an OFF state), and the power amplifier 12 operates (in an ON state). The OFF state of the power amplifier 11 and the ON state of the power amplifier 12 are controlled by the control circuit 71 using a bias signal.

In FIG. 3, the output impedance of each of the power amplifiers 13 and 14 is in an open state. In this case, the output impedance of the power amplifier 14 is rotated 180 degrees on the Smith chart by the transmission line 32. Accordingly, the impedance of the power amplifier 14 seen from the second end 211b of the input-side coil 211 is short-circuited. In this state, a radio frequency signal amplified by the power amplifier 12 reaches the external output terminal 101 via the transformer 21.

In the middle power mode, as illustrated in FIG. 4, the power amplifiers 11 and 13 operate (in the ON state), and the power amplifiers 12 and 14 do not operate (in the OFF state). The ON state of the power amplifier 11 and the OFF state of the power amplifier 12 are controlled by the control circuit 71 using a bias signal. Also, the OFF state of the power amplifier 14 is controlled by the power of the input signal.

In FIG. 4, the output impedance of each of the power amplifiers 12 and 14 is in the open state. In this case, the output impedance of the power amplifier 12 is rotated 180 degrees on the Smith chart by the transmission line 31. Accordingly, the impedance of the power amplifier 12 seen from the second end 212b of the output-side coil 212 is short-circuited. Also, the output impedance of the power amplifier 14 is rotated 180 degrees on the Smith chart by the transmission line 32. Accordingly, the impedance of the power amplifier 14 seen from the second end 211b of the input-side coil 211 is short-circuited. In this state, a radio frequency signal amplified by the power amplifier 11 is further amplified by the power amplifier 13 and reaches the external output terminal 101 via the transformer 21.

In the high power mode, as illustrated in FIG. 5, the power amplifiers 11, 13, and 14 operate (in the ON state), and the power amplifier 12 does not operate (in the OFF state). The ON state of the power amplifier 11 and the OFF state of the power amplifier 12 are controlled by the control circuit 71 using a bias signal. Also, the ON state of the power amplifier 14 is controlled by the power of the input signal.

In FIG. 5, the output impedance of the power amplifier 12 is in the open state. In this case, the output impedance of the power amplifier 12 is rotated 180 degrees on the Smith chart by the transmission line 31. Accordingly, the impedance of the power amplifier 12 seen from the second end 212b of the output-side coil 212 is short-circuited. In this state, a radio frequency signal amplified by the power amplifier 11 is split by the phase shifter 22, the split signals are further amplified by the power amplifiers 13 and 14 and combined by the transformer 21, and the resulting signal reaches the external output terminal 101.

### 1.2.2 Current Consumption in Each Power Mode

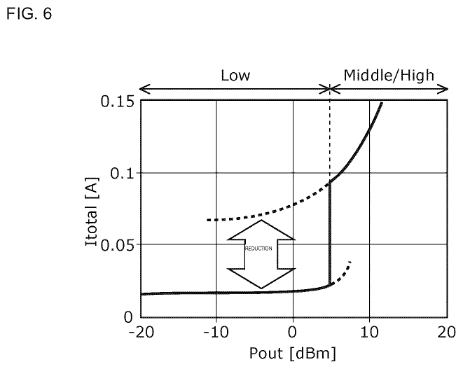

Next, current consumption in each power mode is described with reference to FIG. 6. FIG. 6 is a graph showing the relationship between the output power and the total current consumption of the power amplifier circuit 10 in each power mode. In FIG. 6, the horizontal axis represents output power, and the vertical axis represents total current consumption of the power amplifier circuit 10. Also, the relationship between output power and power modes is indicated at the upper part of the graph.

In FIG. 6, the low power mode is applied to output power less than 5 dBm, and the middle power mode and the high power mode are applied to output power greater than or equal to 5 dBm. Dotted lines indicate current consumption when power modes are not changed.

As is apparent from FIG. 6, as a result of applying the low power mode to the output power less than 5 dBm, the total current consumption of the power amplifier circuit 10 is reduced compared with a case in which the middle power mode is applied. That is, stopping the operations of the power amplifiers 13 and 14 when the output power is low makes it possible to reduce the total power consumption of the power amplifier circuit 10.

### 1.3 Example of Power Amplifier Circuit 10

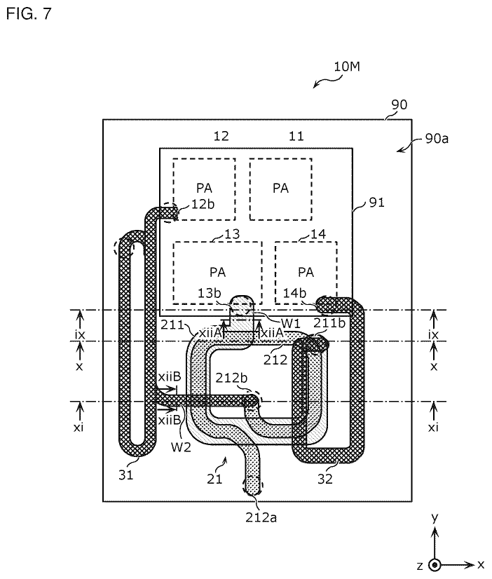

A power amplifier module 10M, which is an example of the power amplifier circuit 10 according to the present embodiment, is described with reference to FIGS. 7 to 11.

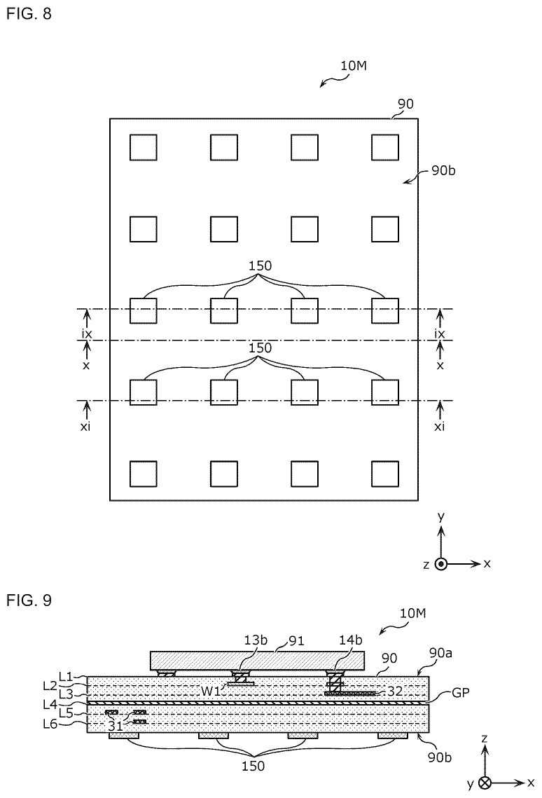

FIG. 7 is a plan view of the power amplifier module 10M of this example as well as a transparent view, which is seen from the positive z-axis side, of the inside of a module substrate 90 and a side of the module substrate 90 closer to a major surface 90a. FIG. 8 is a plan view of the power amplifier module 10M of this example as well as a transparent view, which is seen from the positive z-axis side, of a side of the module substrate 90 closer to a major surface 90b. Each of FIGS. 9 to 11 is a cross-sectional view of the power amplifier module 10M of this example. The cross sections of the power amplifier module 10M illustrated in FIGS. 9 to 11 are taken along line ix-ix, line x-x, and line xi-xi in FIGS. 7 and 8, respectively.

Components in FIGS. 7 to 11 may be provided with letters representing those components to facilitate the understanding of the layout of the components. However, such letters are not provided on actual components. Also, in FIGS. 7 to 11, the illustration of some of wires for connecting multiple components disposed on or in the module substrate 90 is omitted.

The power amplifier module 10M includes the module substrate 90 and multiple pad electrodes 150 in addition to the multiple circuit components included in the power amplifier circuit 10 illustrated in FIG. 1.

The module substrate 90 has the major surfaces 90a and 90b that face each other. The major surfaces 90a and 90b are examples of a first major surface and a second major surface, respectively. In FIGS. 7 and 8, the module substrate 90 has a rectangular shape in plan view. However, the shape of the module substrate 90 is not limited to a rectangle.

As a non-limiting example, the module substrate 90 may be implemented by a low-temperature co-fired ceramics (LTCC) substrate or a high-temperature co-fired ceramics (HTCC) substrate with a multilayer structure formed of multiple dielectric layers, a component built-in substrate, a substrate including a redistribution layer (RDL), or a printed-circuit board.

An integrated circuit 91 is disposed on the major surface 90a. The integrated circuit 91 includes the power amplifiers 11 to 14. The integrated circuit 91 comprises at least one of gallium arsenide (GaAs), silicon germanium (SiGe), and gallium nitride (GaN). Each of the power amplifiers 11 to 14 includes a bipolar transistor, such as a heterojunction bipolar transistor (HBT), as an amplifying element.

The integrated circuit 91 may be implemented by using, for example, a complementary metal oxide semiconductor (CMOS). Specifically, the integrated circuit 91 may be manufactured by a Silicon on Insulator (SOI) process. In this case, each of the power amplifiers 11 to 14 may include a field effect transistor (FET), such as a metal-oxide-semiconductor field effect transistor (MOSFET), as an amplifying element. Semiconductor materials of the integrated circuit 91 are not limited to the above-described examples.

The transformer 21 and the transmission lines 31 and 32 are disposed in the module substrate 90.

The input-side coil 211 and the output-side coil 212 of the transformer 21 are formed as planar wiring patterns in different layers of the module substrate 90. Specifically, the output-side coil 212 is disposed in a layer L1 on the major surface 90a of the module substrate 90. The input-side coil 211 is disposed in a layer L2 inside of the module substrate 90 and is connected to the output terminal 13b of the power amplifier 13 through a wire W1 and a via conductor as illustrated in FIG. 9. In plan view of the module substrate 90, at least a part of the input-side coil 211 overlaps at least a part of the output-side coil 212.

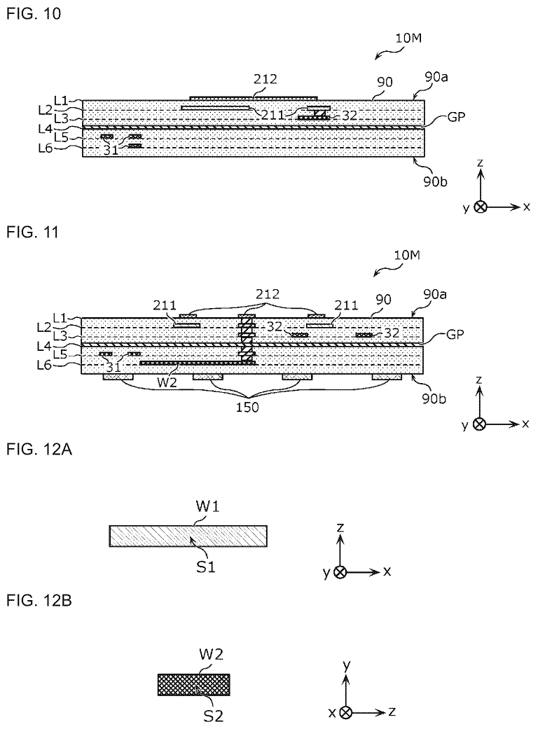

The transmission lines 31 and 32 are disposed in the module substrate 90. The transmission line 31 is disposed in layers different from the transformer 21. Specifically, the transmission line 31 is disposed in layers L5 and L6 lower than the transformer 21 (the input-side coil 211 and the output-side coil 212) and is connected to the output-side coil 212 through a wire W2 and a via conductor as illustrated in FIG. 11. The transmission line 32 is disposed in a layer L3 lower than the transformer 21 (the input-side coil 211 and the output-side coil 212). As illustrated in FIGS. 9 and 10, the transmission line 32 is connected, through via conductors, to the output terminal 14b of the power amplifier 14 and the input-side coil 211.

A layer L4 (or a ground layer), in which a planar ground pattern GP is disposed, is sandwiched between the layers L1 and L2 in which the transformer 21 is disposed and the layers L5 and L6 in which the transmission line 31 is disposed. In other words, the planar ground pattern GP connected to the ground is disposed between the transformer 21 and the transmission line 31.

The wires W1 and W2 are formed in the module substrate 90. The wire W1 is an example of a first wire and connects the output terminal 13b of the power amplifier 13 to the first end 211a of the input-side coil 211. The wire W2 is an example of a second wire and connects the output terminal 12b of the power amplifier 12 to the second end 212b of the output-side coil 212.

FIGS. 12A and 12B are cross-sectional views of the wires W1 and W2 of this example. The cross section of the wire W1 in FIG. 12A is taken along line xiiA-xiiA in FIG. 7. The cross section of the wire W2 in FIG. 12B is taken along line xiiB-xiiB in FIG. 7.

As illustrated in FIGS. 12A and 12B, a cross-sectional area S1 of the wire W1 is greater than a cross-sectional area S2 of the wire W2. Here, the cross-sectional area of a wire indicates the smallest area among the areas of multiple cross sections obtained by cutting the wire with planes that are perpendicular to the direction in which an electric current flows.

Multiple pad electrodes 150 are disposed on the major surface 90b. The multiple pad electrodes 150 are external connection terminals that include ground terminals in addition to the external output terminal 101, the external input terminal 111, and the supply terminal 131 illustrated in FIG. 1. The multiple pad electrodes 150 are connected to, for example, input-output terminals and/or ground terminals on a mother board located in the negative z-axis direction from the power amplifier module 10M. Instead of the multiple pad electrodes 150, multiple bump electrodes or multiple post electrodes may be included in the power amplifier module 10M.

Although the control circuit 71 is not illustrated in FIGS. 7 to 11, the control circuit 71 may be either included in or provided outside of the power amplifier module 10M. When the control circuit 71 is included in the power amplifier module 10M, the control circuit 71 may be disposed on the major surface 90a or stacked on the integrated circuit 91.

Furthermore, the power amplifier module 10M may include a resin member that covers the surface of the module substrate 90 and a part of circuit components, and a shield electrode layer that covers the surface of the resin member. Circuit components (for example, the switch 51 and the filter 61) constituting the radio frequency circuit 1 may also be disposed in or on the module substrate 90. In this case, the power amplifier module 10M may also be referred to as a radio frequency module.

### 1.4 Effects

As described above, the power amplifier circuit 10 according to the present embodiment includes the external input terminal 111, the external output terminal 101, the power amplifiers 11 to 14, the transformer 21 including the input-side coil 211 and the output-side coil 212, and the transmission line 31. The external input terminal 111 is connected to the input terminal 11a of the power amplifier 11 and the input terminal 12a of the power amplifier 12; the output terminal 11b of the power amplifier 11 is connected to the input terminal 13a of the power amplifier 13 and the input terminal 14a of the power amplifier 14; the output terminal 13b of the power amplifier 13 is connected to the first end 211a of the input-side coil 211; the output terminal 14b of the power amplifier 14 is connected to the second end 211b of the input-side coil 211; the external output terminal 101 is connected to the first end 212a of the output-side coil 212; and the output terminal 12b of the power amplifier 12 is connected to the second end 212b of the output-side coil 212 via the transmission line 31.

With this configuration, when a radio frequency signal is amplified by the power amplifier 11, the amplified radio frequency signal can be further amplified by the power amplifiers 13 and 14. Here, because the transmission line 31 is connected between the power amplifier 12 and the output-side coil 212 of the transformer 21, the impedance of the power amplifier 12 seen from the output-side coil 212 can be short-circuited without using a switch. As a result, the signal amplified by the power amplifiers 13 and 14 is output from the external output terminal 101 via the transformer 21. That is, the power amplifier circuit 10 can be used as a multi-stage amplifier circuit including multiple power amplifiers in the output stage. This in turn makes it possible to increase the gain and thereby makes it possible to increase the output power. On the other hand, when a radio frequency signal is amplified by the power amplifier 12, the amplified radio frequency signal can be output from the external output terminal 101 via the output-side coil 212 of the transformer 21 without being further amplified by the power amplifiers 13 and 14. That is, the power amplifier circuit 10 can be used as a single stage amplifier circuit. This in turn makes it possible to reduce the power consumption when the output power is low and thereby makes it possible to improve the efficiency. Thus, in the power amplifier circuit 10, the power amplifiers 13 and 14 connected to the transformer 21 can be bypassed without using a switch. This in turn makes it possible to improve the efficiency when the output power is relatively low while suppressing the increase in the number of switch components.

Also, for example, the power amplifier circuit 10 according to the present embodiment may further include the control circuit 71 that has the first power mode (the high power mode and/or the middle power mode) corresponding to the first output power and the second power mode (the low power mode) corresponding to the second output power lower than the first output power. In the first power mode, the control circuit 71 may be configured to control the power amplifier 11 to be in the ON state and control the power amplifier 12 to be in the OFF state; and in the second power mode, the control circuit 71 may be configured to control the power amplifier 11 to be in the OFF state and control the power amplifier 12 to be in the ON state.

With this configuration, it is possible to achieve higher first output power and reduce the power consumption at lower second output power by controlling the ON and OFF states of the power amplifiers 11 and 12.

Also, for example, in the power amplifier circuit 10 according to the present embodiment, the control circuit 71 may be configured to control the ON and OFF states of the power amplifiers 11 and 12 by using a bias signal.

This configuration makes it possible to control the ON and OFF states of the power amplifiers 11 and 12 by using a bias signal and eliminates the need for a switch for changing the ON and OFF states of the power amplifiers 11 and 12. This in turn makes it possible to reduce loss caused by the switch and thereby makes it possible to improve the efficiency.

Also, for example, the power amplifier circuit 10 according to the present embodiment may further include the transmission line 32, and the output terminal 14b of the power amplifier 14 may be connected to the second end 211b of the input-side coil 211 via the transmission line 32.

With this configuration, because the transmission line 32 is connected between the power amplifier 14 and the input-side coil 211, the impedance of the power amplifier 14 seen from the input-side coil 211 can be short-circuited when the power amplifier 14 is not in operation. This in turn makes it possible to operate the power amplifier 13 to output an amplified radio frequency signal from the external output terminal 101 via the transformer 21 when the power amplifier 14 is not in operation.

For example, in the power amplifier circuit 10 according to the present embodiment, the power amplifier 13 may be a carrier amplifier, and the power amplifier 14 may be a peak amplifier.

This makes it possible to use a Doherty amplifier as an output stage and thereby makes it possible to improve the efficiency.

For example, the power amplifier module 10M according to the example of the present embodiment includes the module substrate 90 on or in which the power amplifiers 11 to 14, the transformer 21, and the transmission line 31 are disposed; the output terminal 13b of the power amplifier 13 is connected to the first end 211a of the input-side coil 211 by using the wire W1 formed in the module substrate 90; the output terminal 12b of the power amplifier 12 is connected to the second end 212b of the output-side coil 212 by using the wire W2 formed in the module substrate 90; and the cross-sectional area S1 of the wire W1 may be greater than the cross-sectional area S2 of the wire W2.

With this configuration, it is possible to reduce the loss by making the cross-sectional area S1 of the wire W1, which transmits a radio frequency signal with higher power, relatively large. Also, with this configuration, it is possible to reduce the size of the power amplifier module 10M by making the cross-sectional area S2 of the wire W2, which transmits a radio frequency signal with lower power, relatively small.

For example, the power amplifier module 10M according to the example of the present embodiment may include the module substrate 90 that includes multiple layers and on or in which the power amplifiers 11 to 14, the transformer 21, and the transmission line 31 are disposed; and the transmission line 31 and the transformer 21 may be disposed in different layers of the module substrate 90.

This configuration makes it possible to improve the isolation between the transmission line 31 and the transformer 21 and thereby makes it possible to improve the quality of radio frequency signals.

For example, in the power amplifier module 10M according to the example of the present embodiment, the multiple layers of the module substrate 90 may include the ground layer (L4) in which the planar ground pattern GP is disposed, and the ground layer may be disposed between the layers (L1 and L2) in which the transformer 21 is disposed and the layers (L5 and L6) in which the transmission line 31 is disposed.

This configuration makes it possible to further improve the isolation between the transmission line 31 and the transformer 21 and thereby makes it possible to further improve the quality of radio frequency signals.

A power amplification method according to the present embodiment has a first power mode (the high power mode and/or the middle power mode) corresponding to first output power and a second power mode (the low power mode) corresponding to second output power lower than the first output power. The power amplification method includes: in the first power mode, controlling the power amplifier 11, which is connected to the input-side coil 211 of the transformer 21 via the power amplifiers 13 and 14, to be in an ON state and controlling the power amplifier 12, which is connected to the output-side coil 212 of the transformer 21 via the transmission line 31, to be in an OFF state; and in the second power mode, controlling the power amplifier 11 to be in the OFF state and controlling the power amplifier 12 to be in the ON state.

With this method, by controlling the ON and OFF states of the power amplifiers 11 and 12, higher first output power can be achieved using the power amplifiers 11, 13, and 14, and lower second output power can be achieved using the power amplifier 12 and without using the power amplifiers 13 and 14. Accordingly, in a case where multiple power amplifiers connected to a transformer are used as an output stage of a multi-stage amplifier circuit, the above method makes it possible to improve the efficiency when output power is relatively low.

### Second Embodiment

Next, a second embodiment is described. The second embodiment mainly differs from the first embodiment in that the output terminal 12b of the power amplifier 12 is connected to the input-side coil 211 of the transformer 21. Below, differences between the first embodiment and the second embodiment are mainly described with reference to the drawings.

### 2.1 Circuit Configuration of Power Amplifier Circuit 10A

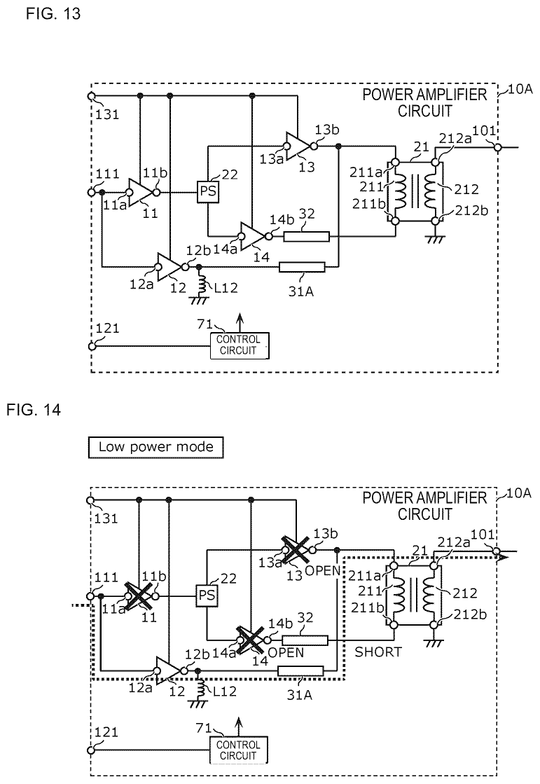

A circuit configuration of a power amplifier circuit 10A according to the present embodiment is described with reference to FIG. 13. FIG. 13 is a circuit diagram of the power amplifier circuit 10A according to the present embodiment.

The power amplifier circuit 10A includes power amplifiers 11 to 14, a transformer 21, a phase shifter 22, transmission lines 31A and 32, a control circuit 71, an external output terminal 101, an external input terminal 111, a control terminal 121, a supply terminal 131, and an inductor L12.

The transmission line 31A is an example of a first transmission line and can rotate the load impedance by 90 degrees on the Smith chart. The transmission line 31A may be implemented by, for example, a ⅛ wavelength transmission line. The length of the transmission line 31A is determined based on the predetermined band. The transmission line 31A may also be referred to as a phase adjuster or a phase shifter.

The transmission line 31A is connected between the power amplifier 12 and the transformer 21. Specifically, one end of the transmission line 31A is connected to the output terminal 12b of the power amplifier 12, and another end of the transmission line 31A is connected to the first end 211a of the input-side coil 211 of the transformer 21. With this connection configuration, the transmission line 31A can shift the phase of a transmission signal, which has been amplified by the power amplifier 12 and is in the predetermined band, by −45 degrees (or delay the transmission signal by 45 degrees).

The transmission line 31A may include at least one of an inductor and a capacitor. For example, the transmission line 31A may include one or more inductors and/or capacitors connected in series to a path that connects the power amplifier 12 to the transformer 21 and may include one or more inductors and/or capacitors connected between the path and the ground. This configuration makes it possible to shorten the length of the transmission line 31A.

The inductor L12 is connected between the ground and a path connecting the output terminal 12b of the power amplifier 12 to the transmission line 31A. The inductor L12 can rotate the load impedance by 90 degrees on the Smith chart.

The angle of rotation of the load impedance on the Smith chart caused by each of the inductor L12 and the transmission line 31A is not limited to 45 degrees as long as the load impedance can be rotated 180 degrees on the Smith chart by a combination of the inductor L12 and the transmission line 31A.

### 2.2 Operations of Power Amplifier Circuit 10A

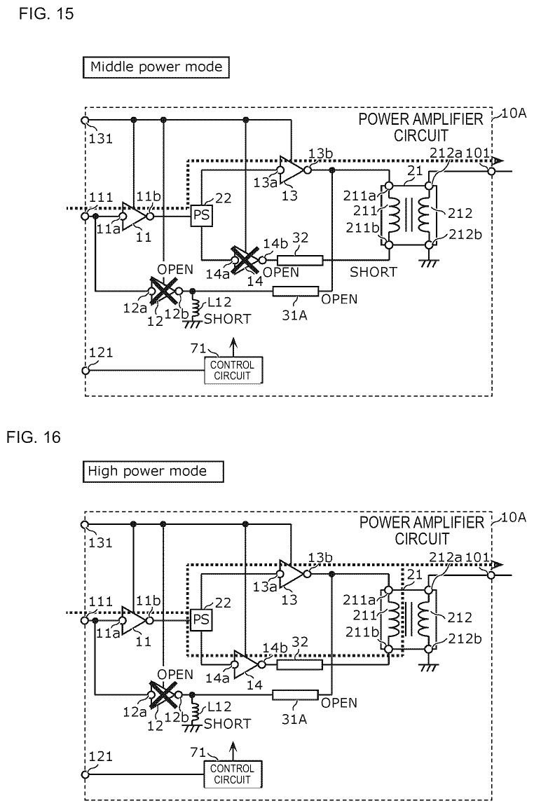

Operations of the power amplifier circuit 10A according to the present embodiment are described with reference to FIGS. 14 to 16. FIG. 14 is a circuit state diagram of the power amplifier circuit 10A in the low power mode according to the present embodiment. FIG. 15 is a circuit state diagram of the power amplifier circuit 10A in the middle power mode according to the present embodiment. FIG. 16 is a circuit state diagram of the power amplifier circuit 10A in the high power mode according to the present embodiment.

In the low power mode, as illustrated in FIG. 14, the power amplifiers 11, 13, and 14 do not operate (in an OFF state), and the power amplifier 12 operates (in an ON state). The OFF state of the power amplifier 11 and the ON state of the power amplifier 12 are controlled by the control circuit 71 using a bias signal.

In FIG. 14, the output impedance of each of the power amplifiers 13 and 14 is in the open state. In this case, the output impedance of the power amplifier 14 is rotated 180 degrees on the Smith chart by the transmission line 32. Accordingly, the impedance of the power amplifier 14 seen from the second end 211b of the input-side coil 211 is short-circuited. In this state, a radio frequency signal amplified by the power amplifier 12 reaches the external output terminal 101 via the transformer 21.

In the middle power mode, as illustrated in FIG. 15, the power amplifiers 11 and 13 operate (in the ON state), and the power amplifiers 12 and 14 do not operate (in the OFF state). The ON state of the power amplifier 11 and the OFF state of the power amplifier 12 are controlled by the control circuit 71 using a bias signal. Also, the OFF state of the power amplifier 14 is controlled by the power of the input signal.

In FIG. 15, the output impedance of each of the power amplifiers 12 and 14 is in the open state. In this state, the impedance at the ground end of the inductor L12 (short-circuited) is rotated 180 degrees on the Smith chart by the inductor L12 and the transmission line 31A. Accordingly, the impedance of the power amplifier 12 seen from the first end 211a of the input-side coil 211 is in the open state. Furthermore, the output impedance of the power amplifier 14 is rotated 180 degrees on the Smith chart by the transmission line 32. Accordingly, the impedance of the power amplifier 14 seen from the second end 211b of the input-side coil 211 is short-circuited. In this state, a radio frequency signal amplified by the power amplifier 11 is further amplified by the power amplifier 13 and reaches the external output terminal 101 via the transformer 21.

In the high power mode, as illustrated in FIG. 16, the power amplifiers 11, 13 and, 14 operate (in the ON state), and the power amplifier 12 does not operate (in the OFF state). The ON state of the power amplifier 11 and the OFF state of the power amplifier 12 are controlled by the control circuit 71 using a bias signal. Also, the ON state of the power amplifier 14 is controlled by the power of the input signal.

In FIG. 16, the output impedance of the power amplifier 12 is in the open state. In this state, the output impedance of the power amplifier 12 is rotated 360 degrees on the Smith chart by the inductor L12 and the transmission line 31A. Accordingly, the impedance of the power amplifier 12 seen from the first end 211a of the input-side coil 211 is in the open state. In this state, a radio frequency signal amplified by the power amplifier 11 is split by the phase shifter 22, the split signals are further amplified by the power amplifiers 13 and 14 and combined by the transformer 21, and the resulting signal reaches the external output terminal 101.

In the above example, the ON and OFF states of the power amplifiers 11 and 12 are controlled using a bias signal. However, the present disclosure is not limited to this example. For example, the ON and OFF states of the power amplifiers 11 and 12 may be controlled using a power-supply voltage. As another example, the ON and OFF states of the power amplifiers 11 and 12 may be controlled by a switch that switches components to which a radio frequency signal is input.

### 2.3 Example of Power Amplifier Circuit 10A

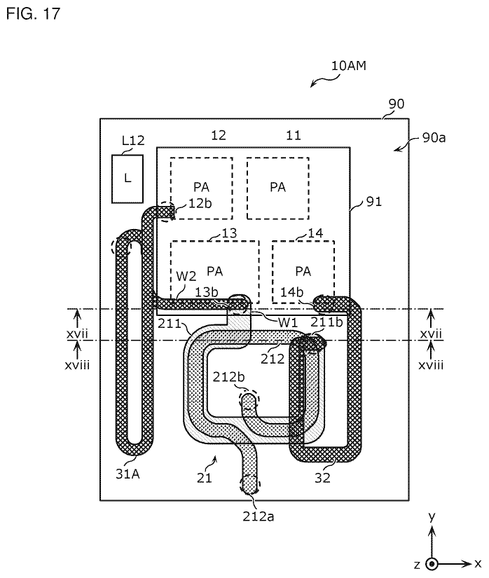

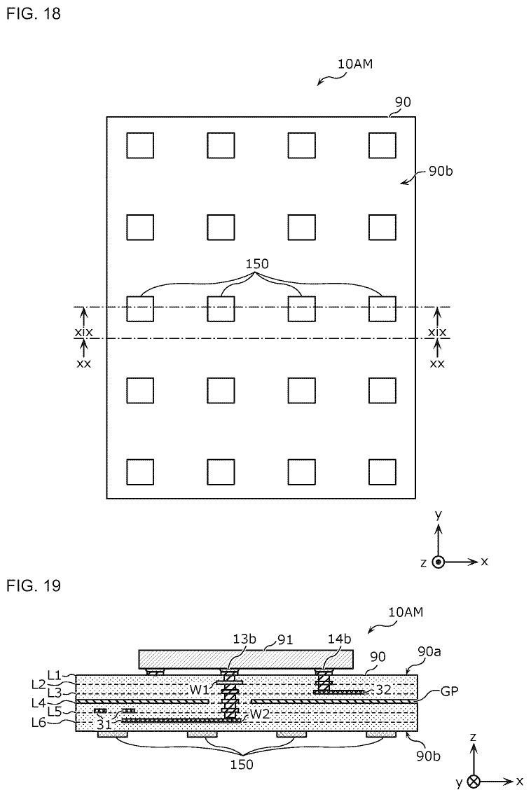

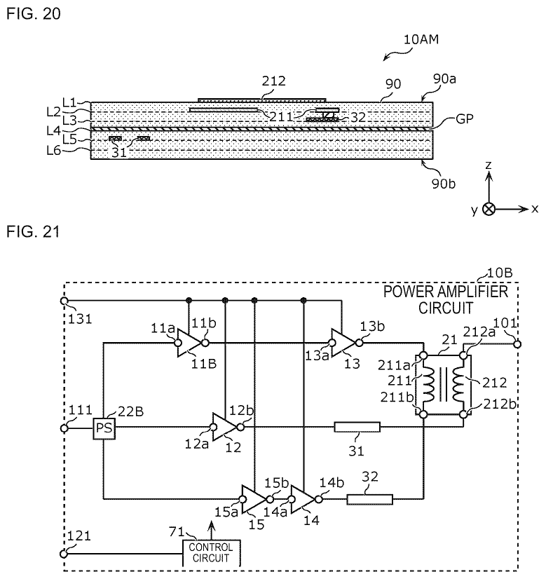

A power amplifier module 10AM, which is an example of the power amplifier circuit 10A according to the present embodiment, is described with reference to FIGS. 17 to 20. FIG. 17 is a plan view of the power amplifier module 10AM of this example as well as a transparent view, which is seen from the positive z-axis side, of the inside of the module substrate 90a and a side of the module substrate 90 closer to the major surface 90a. FIG. 18 is a plan view of the power amplifier module 10AM of this example as well as a transparent view, which is seen from the positive z-axis side, of a side of the module substrate 90 closer to the major surface 90b. Each of FIGS. 19 and 20 is a cross-sectional view of the power amplifier module LOAM of this example. The cross sections of the power amplifier module LOAM illustrated in FIGS. 19 and 20 are taken along line xix-xix and line xx-xx in FIGS. 17 and 18, respectively.

Components in FIGS. 17 to 20 may be provided with letters representing those components to facilitate the understanding of the layout of the components. However, such letters are not provided on actual components. Also, in FIGS. 17 to 20, the illustration of some of wires for connecting multiple components disposed on or in the module substrate 90 is omitted.

The power amplifier module 10AM includes the module substrate 90 and multiple pad electrodes 150 in addition to the multiple circuit components included in the power amplifier circuit 10A illustrated in FIG. 13.

The inductor L12 is disposed on the major surface 90a in addition to the integrated circuit 91. The inductor L12 is mounted as a surface mount device (SMD). The inductor L12 is not limited to an SMD and may be implemented by, for example, a wire in the module substrate 90.

The transformer 21 and the transmission lines 31A and 32 are disposed in the module substrate 90. The transmission line 31A is disposed in a layer different from the transformer 21. Specifically, the transmission line 31A is disposed in layers L5 and L6 lower than the transformer 21 (the input-side coil 211 and the output-side coil 212) and is connected to the input-side coil 211 through a wire W2, a via conductor, and a wire W1 as illustrated in FIG. 19.

A layer L4 (or a ground layer), in which a planar ground pattern GP is disposed, is sandwiched between layers L1 and L2 in which the transformer 21 is disposed and layers L5 and L6 in which the transmission line 31A is disposed. In other words, the planar ground pattern GP connected to the ground is disposed between the transformer 21 and the transmission line 31A.

### 2.4 Effects

As described above, the power amplifier circuit 10A of the present embodiment includes the external input terminal 111, the external output terminal 101, the power amplifiers 11 to 14, and the transformer 21 including the input-side coil 211 and the output-side coil 212. The external input terminal 111 is connected to the input terminal 11a of the power amplifier 11 and the input terminal 12a of the power amplifier 12, the output terminal 11b of the power amplifier 11 is connected to the input terminal 13a of the power amplifier 13 and the input terminal 14a of the power amplifier 14, the output terminal 12b of the power amplifier 12 and the output terminal 13b of the power amplifier 13 are connected to the first end 211a of the input-side coil 211, the output terminal 14b of the power amplifier 14 is connected to the second end 211b of the input-side coil 211, the first end 212a of the output-side coil 212 is connected to the external output terminal 101, and the second end 212b of the output-side coil 212 is connected to the ground.

With this configuration, when a radio frequency signal is amplified by the power amplifier 11, the amplified radio frequency signal can be further amplified by the power amplifiers 13 and 14 and output from the external output terminal 101 via the transformer 21. That is, the power amplifier circuit 10A can be used as a multi-stage amplifier circuit including multiple power amplifiers in the output stage. This in turn makes it possible to increase the gain and thereby makes it possible to increase the output power. On the other hand, when a radio frequency signal is amplified by the power amplifier 12, the amplified radio frequency signal can be output from the external output terminal 101 via the transformer 21 without being further amplified by the power amplifiers 13 and 14. That is, the power amplifier circuit 10A can be used as a single stage amplifier circuit. This in turn makes it possible to reduce the power consumption when the output power is low and thereby makes it possible to improve the efficiency. Thus, in the power amplifier circuit 10A, the power amplifiers 13 and 14 connected to the transformer 21 can be bypassed without using a switch. This in turn makes it possible to improve the efficiency when the output power is relatively low while suppressing the increase in the number of switch components.

For example, the power amplifier circuit 10A according to the present embodiment may further include the transmission line 31A and the inductor L12. The transmission line 31A may be connected between the output terminal 12b of the power amplifier 12 and the first end 211a of the input-side coil 211, and the inductor L12 may be connected between the ground and a path connecting the output terminal 12b of the power amplifier 12 to the transmission line 31A.

With this configuration, because the transmission line 31A and the inductor L12 are connected between the output terminal 12b of the power amplifier 12 and the first end 211a of the input-side coil 211, the impedance of the power amplifier 12 seen from the first end 211a of the input-side coil 211 can be more stably set in the open state when the power amplifier 12 is not in operation. This in turn makes it possible to reduce the mismatching loss caused by the power amplifier 12 when the power amplifier 12 is not in operation.

For example, the power amplifier circuit 10A according to the present embodiment may further include the control circuit 71 having the first power mode (the high power mode and/or the middle power mode) corresponding to the first output power and the second power mode (the low power mode) corresponding to the second output power lower than the first output power. In the first power mode, the control circuit 71 may be configured to control the power amplifier 11 to be in the ON state and control the power amplifier 12 to be in the OFF state. In the second power mode, the control circuit 71 may be configured to control the power amplifier 11 to be in the OFF state and control the power amplifier 12 to be in the ON state.

This configuration makes it possible to achieve higher first output power and reduce the power consumption at lower second output power by controlling the ON and OFF states of the power amplifiers 11 and 12.

For example, in the power amplifier circuit 10A of the present embodiment, the control circuit 71 may control the ON and OFF states of the power amplifiers 11 and 12 by using a bias signal.

This configuration makes it possible to control the ON and OFF states of the power amplifiers 11 and 12 by using a bias signal and eliminates the need for a switch for changing the ON and OFF states of the power amplifiers 11 and 12. This in turn makes it possible to reduce loss caused by the switch and thereby makes it possible to improve the efficiency.

For example, the power amplifier circuit 10A according to the present embodiment may further include the transmission line 32, and the output terminal 14b of the power amplifier 14 may be connected to the second end 211b of the input-side coil 211 via the transmission line 32.

With this configuration, because the transmission line 32 is connected between the power amplifier 14 and the input-side coil 211, the impedance of the power amplifier 14 seen from the input-side coil 211 can be short-circuited when the power amplifier 14 is not in operation. This in turn makes it possible to operate the power amplifier 13 to output an amplified radio frequency signal from the external output terminal 101 via the transformer 21 when the power amplifier 14 is not in operation.

For example, in the power amplifier circuit 10A according to the present embodiment, the power amplifier 13 may be a carrier amplifier, and the power amplifier 14 may be a peak amplifier.

This makes it possible to use a Doherty amplifier as an output stage and thereby makes it possible to improve the efficiency.

For example, the power amplifier module LOAM according to the example of the present embodiment includes the module substrate 90 on or in which the power amplifiers 11 to 14 and the transformer 21 are disposed; the output terminal 13b of the power amplifier 13 is connected to the first end 211a of the input-side coil 211 by using the wire W1 formed in the module substrate 90; the output terminal 12b of the power amplifier 12 is connected to the first end 211a of the input-side coil 211 by using the wire W2 formed in the module substrate 90; and the cross-sectional area S1 of the wire W1 may be greater than the cross-sectional area S2 of the wire W2.

This configuration makes it possible to reduce the loss by making the cross-sectional area S1 of the wire W1, which transmits a radio frequency signal with higher power, relatively large. Also, with this configuration, it is possible to reduce the size of the power amplifier module 10AM by making the cross-sectional area S2 of the wire W2, which transmits a radio frequency signal with lower power, relatively small.

For example, the power amplifier module 10AM according to the example of the present embodiment may include the module substrate 90 that includes multiple layers and on or in which the power amplifiers 11 to 14, the transformer 21, and the transmission line 31A are disposed; and the transmission line 31A and the transformer 21 may be disposed in different layers of the module substrate 90.

This configuration makes it possible to improve the isolation between the transmission line 31A and the transformer 21 and thereby makes it possible to improve the quality of radio frequency signals.

For example, in the power amplifier module 10AM according to the example of the present embodiment, the multiple layers of the module substrate 90 may include the ground layer (L4) in which the planar ground pattern GP is disposed, and the ground layer may be disposed between the layers (L1 and L2) in which the transformer 21 is disposed and the layers (L5 and L6) in which the transmission line 31A is disposed.

This configuration makes it possible to further improve the isolation between the transmission line 31A and the transformer 21 and thereby makes it possible to further improve the quality of radio frequency signals.

A power amplification method according to the present embodiment has a first power mode (the high power mode and/or the middle power mode) corresponding to first output power and a second power mode (the low power mode) corresponding to second output power lower than the first output power. The power amplification method includes: in the first power mode, controlling the power amplifier 11, which is connected to the input-side coil 211 of the transformer 21 via the power amplifiers 13 and 14, to be in the ON state and controlling the power amplifier 12, which is connected to the input-side coil 211 of the transformer 21 not via the power amplifiers 13 and 14, to be in the OFF state; and in the second power mode, controlling the power amplifier 11 to be in the OFF state and controlling the power amplifier 12 to be in the ON state.

With this method, by controlling the ON and OFF states of the power amplifiers 11 and 12, higher first output power can be achieved using the power amplifiers 11, 13, and 14, and lower second output power can be achieved using the power amplifier 12 and without using the power amplifiers 13 and 14. Accordingly, in a case where multiple power amplifiers connected to a transformer are used as an output stage of a multi-stage amplifier circuit, the above configuration makes it possible to improve the efficiency when output power is relatively low.

### (Variations)

In each of the power amplifier circuits of the above embodiments, both of the power amplifiers 13 and 14 (the output stage) are connected to one power amplifier 11 (the input stage). However, the present disclosure is not limited to these embodiments. For example, the power amplifiers 13 and 14 (the output stage) may be connected to two different power amplifiers (the input stage). Such variations are described below.

### 3.1 Variation of First Embodiment

First, a power amplifier circuit 10B according to a variation of the first embodiment is described with reference to FIG. 21 focusing on differences from the power amplifier circuit 10 according to the first embodiment. FIG. 21 is a circuit diagram of the power amplifier circuit 10B according to the variation of the first embodiment.

The power amplifier circuit 10B according to this variation differs from the power amplifier circuit 10 according to the first embodiment in that the power amplifier circuit 10B includes a power amplifier 11B and a phase shifter 22B instead of the power amplifier 11 and the phase shifter 22 and further includes a power amplifier 15.

The phase shifter 22B is connected between the external input terminal 111 and each of the power amplifiers 11B, 12, and 15. Specifically, the input end of the phase shifter 22B is connected to the external input terminal 111. Also, each of three output ends of the phase shifter 22B is connected to the corresponding one of the power amplifiers 11B, 12, and 15.

With this connection configuration, the phase shifter 22B can split a signal input from the external input terminal 111 and output the split signals to an input terminal 11a of the power amplifier 11B, the input terminal 12a of the power amplifier 12, and an input terminal 15a of the power amplifier 15. Also, the phase shifter 22B can adjust the phases of the three split signals. For example, the phase shifter 22B can shift a signal to be input to the power amplifier 15 by −90 degrees (or delay the signal by 90 degrees) with respect to a signal to be input to the power amplifier 11B. The phase adjustment performed by the phase shifter 22B is not limited to the above example. As another example, the phase shifter 22B may appropriately change the phase differences among the three split signals based on the internal configuration of the power amplifier circuit 10B.

The power amplifier 11B is connected between the phase shifter 22B and the power amplifier 13. Specifically, the input terminal 11a of the power amplifier 11B is connected to the phase shifter 22B. The output terminal 11b of the power amplifier 11B is connected to the input terminal 13a of the power amplifier 13. That is, in this variation, the output terminal 11b of the power amplifier 11B is not connected to the input terminal 14a of the power amplifier 14.

With this connection configuration, the power amplifier 11B can amplify a transmission signal in the predetermined band received via the external input terminal 111 by using the power-supply voltage supplied via the supply terminal 131. The transmission signal amplified by the power amplifier 11B is supplied to the power amplifier 13. The power amplifier 11B corresponds to an input stage (or a drive stage) of a multi-stage amplifier circuit and constitutes the multi-stage amplifier circuit together with the power amplifier 13.

The power amplifier 15 is connected between the phase shifter 22B and the power amplifier 14. Specifically, the input terminal 15a of the power amplifier 15 is connected to the phase shifter 22B. An output terminal 15b of the power amplifier 15 is connected to the input terminal 14a of the power amplifier 14.

With this connection configuration, the power amplifier 15 can amplify a transmission signal in the predetermined band received via the external input terminal 111 by using the power-supply voltage supplied via the supply terminal 131. The transmission signal amplified by the power amplifier 15 is supplied to the power amplifier 14. The power amplifier 15 corresponds to an input stage (or a drive stage) of a multi-stage amplifier circuit and constitutes the multi-stage amplifier circuit together with the power amplifier 14.

### 3.2 Variation of Second Embodiment

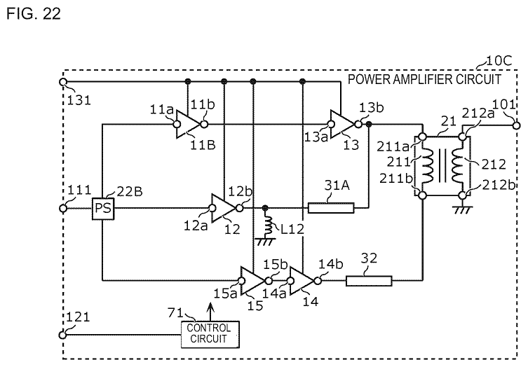

Next, a power amplifier circuit 10C according to a variation of the second embodiment is described with reference to FIG. 22 focusing on differences from the power amplifier circuit 10A according to the second embodiment. FIG. 22 is a circuit diagram of the power amplifier circuit 10C according to the variation of the second embodiment.

The power amplifier circuit 10C according to this variation differs from the power amplifier circuit 10A according to the second embodiment in that the power amplifier circuit 10C includes the power amplifier 11B and the phase shifter 22B instead of the power amplifier 11 and the phase shifter 22 and further includes the power amplifier 15.

The power amplifiers 11B and 15 and the phase shifter 22B are the same as those in the variation of the first embodiment, and therefore their descriptions are omitted here.

### (Other Variations)

Power amplifier circuits, radio frequency circuits, communication devices, and power amplification methods according to the embodiments of the present disclosure are described above. However, power amplifier circuits, radio frequency circuits, communication devices, and power amplification methods according to the present disclosure are not limited to those described in the above embodiments. The present disclosure may also include other embodiments implemented by combining components in the above-described embodiments, variations obtained by making various modifications conceivable by a person skilled in the art to the embodiments without departing from the spirit of the present disclosure, and various devices including the radio frequency circuits described above.

For example, in the power amplifier circuits according to the above embodiments, other circuit elements and wires may be inserted in paths connecting circuit elements and signal paths illustrated in the drawings. For example, an impedance matching circuit may be inserted between the filter 61 and the power amplifier circuit 10 and/or between the filter 61 and the antenna connection terminal 100. Similarly, an impedance matching circuit may be inserted between any other two circuit elements. An impedance matching circuit may be comprised of, for example, an inductor and/or a capacitor.

As another example, in each of the power amplifier circuits according to the above embodiments, one or more power amplifiers corresponding to an intermediate stage may be connected between a power amplifier corresponding to an input stage and a power amplifier corresponding to an output stage.

In the above embodiments, it is assumed that the same power-supply voltage is supplied to multiple power amplifiers. However, the present disclosure is not limited to the above embodiments. For example, power-supply voltages with different tracking methods or different voltage levels may be supplied to multiple power amplifiers. In this case, a power amplifier circuit may have multiple supply terminals.

### INDUSTRIAL APPLICABILITY

The present disclosure can be widely used for communication devices, such as a mobile phone, as a power amplifier circuit or a radio frequency circuit disposed in a multiband front-end unit.

### REFERENCE SIGNS LIST

1 radio frequency circuit
2 antenna
3 RFIC
4 BBIC
5 power supply circuit
6 communication device
10, 10A, 10B, 10C power amplifier circuit
10M, 10AM power amplifier module
11, 11B, 12, 13, 14, 15 power amplifier
11a, 12a, 13a, 14a, 15a input terminal
11b, 12b, 13b, 14b, 15b output terminal
21 transformer
22, 22B phase shifter
31, 31A, 32 transmission line
51 switch
61 filter
71 control circuit
90 module substrate
90a, 90b major surface
91 integrated circuit
100 antenna connection terminal
101 external output terminal
110, 111 external input terminal
120, 121 control terminal
130, 131 supply terminal
150 pad electrode
211 input-side coil
211a first end of input-side coil
211b second end of input-side coil
212 output-side coil
212a first end of output-side coil
212b second end of output-side coil
511, 512, 513 terminal
C111, C112, C121, C122 capacitor
GP planar ground pattern
L1, L2, L3, L4, L5, L6 layer
L12 inductor
R11, R12 resistor
S1, S2 cross-sectional area
T11, T12 amplifier transistor
W1, W2 wire

1. A power amplifier circuit comprising:
an external input terminal and an external output terminal;
a first power amplifier, a second power amplifier, a third power amplifier, and a fourth power amplifier;
a transformer including an input-side coil and an output-side coil; and
a first transmission line, wherein
the external input terminal is connected to an input terminal of the first power amplifier and an input terminal of the second power amplifier,
an output terminal of the first power amplifier is connected to an input terminal of the third power amplifier and an input terminal of the fourth power amplifier,
an output terminal of the third power amplifier is connected to a first end of the input-side coil,
an output terminal of the fourth power amplifier is connected to a second end of the input-side coil,
the external output terminal is connected to a first end of the output-side coil, and
an output terminal of the second power amplifier is connected to a second end of the output-side coil via the first transmission line.

2. The power amplifier circuit according to claim 1, further comprising:
a control circuit having a first power mode corresponding to first output power and a second power mode corresponding to second output power lower than the first output power, wherein
the control circuit is configured to
in the first power mode, control the first power amplifier to be in an ON state and control the second power amplifier to be in an OFF state, and
in the second power mode, control the first power amplifier to be in the OFF state and control the second power amplifier to be in the ON state.

3. The power amplifier circuit according to claim 2, wherein
the control circuit is configured to control the ON state and the OFF state of the first power amplifier and the second power amplifier by using a bias signal.

4. The power amplifier circuit according to claim 1, further comprising:
a second transmission line, wherein
the output terminal of the fourth power amplifier is connected to the second end of the input-side coil via the second transmission line.

5. The power amplifier circuit according to claim 4, wherein
the third power amplifier is a carrier amplifier; and
the fourth power amplifier is a peak amplifier.

6. The power amplifier circuit according to claim 1, further comprising:
a module substrate on or in which the first power amplifier, the second power amplifier, the third power amplifier, the fourth power amplifier, the transformer, and the first transmission line are disposed, wherein
the output terminal of the third power amplifier is connected to the first end of the input-side coil by using a first wire formed in the module substrate;
the output terminal of the second power amplifier is connected to the second end of the output-side coil by using a second wire formed in the module substrate; and
a cross-sectional area of the first wire is greater than a cross-sectional area of the second wire.

7. The power amplifier circuit according to claim 1, further comprising:
a module substrate that includes multiple layers and on or in which the first power amplifier, the second power amplifier, the third power amplifier, the fourth power amplifier, the transformer, and the first transmission line are disposed, wherein
the first transmission line and the transformer are disposed in different layers of the module substrate.

8. The power amplifier circuit according to claim 7, wherein
the multiple layers include a ground layer in which a planar ground pattern is disposed; and
the ground layer is disposed between a layer in which the transformer is disposed and a layer in which the first transmission line is disposed.

9. A power amplification method comprising:
in a first power mode corresponding to first output power, controlling a first power amplifier, which is connected to an input-side coil of a transformer via a third power amplifier and a fourth power amplifier, to be in an ON state and controlling a second power amplifier, which is connected via a transmission line to an output-side coil of the transformer, to be in an OFF state; and
in a second power mode corresponding to second output power lower than the first output power, controlling the first power amplifier to be in the OFF state and controlling the second power amplifier to be in the ON state.

10. A power amplifier circuit comprising:
an external input terminal and an external output terminal;
a first power amplifier, a second power amplifier, a third power amplifier, and a fourth power amplifier; and
a transformer including an input-side coil and an output-side coil, wherein
the external input terminal is connected to an input terminal of the first power amplifier and an input terminal of the second power amplifier,
an output terminal of the first power amplifier is connected to an input terminal of the third power amplifier and an input terminal of the fourth power amplifier,
an output terminal of the second power amplifier and an output terminal of the third power amplifier are connected to a first end of the input-side coil,
an output terminal of the fourth power amplifier is connected to a second end of the input-side coil,
a first end of the output-side coil is connected to the external output terminal, and
a second end of the output-side coil is connected to a ground.

11. The power amplifier circuit according to claim 10, further comprising:
a first transmission line and an inductor, wherein
the first transmission line is connected between the output terminal of the second power amplifier and the first end of the input-side coil, and
the inductor is connected between the ground and a path connecting the output terminal of the second power amplifier to the first transmission line.

12. The power amplifier circuit according to claim 10, further comprising:
a control circuit having a first power mode corresponding to first output power and a second power mode corresponding to second output power lower than the first output power, wherein
the control circuit is configured to
in the first power mode, control the first power amplifier to be in an ON state and control the second power amplifier to be in an OFF state, and
in the second power mode, control the first power amplifier to be in the OFF state and control the second power amplifier to be in the ON state.

13. The power amplifier circuit according to claim 12, wherein
the control circuit is configured to control the ON state and the OFF state of the first power amplifier and the second power amplifier by using a bias signal.

14. The power amplifier circuit according to claim 10, further comprising:
a second transmission line, wherein
the output terminal of the fourth power amplifier is connected to the second end of the input-side coil via the second transmission line.

15. The power amplifier circuit according to claim 14, wherein
the third power amplifier is a carrier amplifier; and
the fourth power amplifier is a peak amplifier.

16. The power amplifier circuit according to claim 10, further comprising:
a module substrate on or in which the first power amplifier, the second power amplifier, the third power amplifier, the fourth power amplifier, and the transformer are disposed, wherein
the output terminal of the third power amplifier is connected to the first end of the input-side coil by using a first wire formed in the module substrate,
the output terminal of the second power amplifier is connected to the first end of the input-side coil by using a second wire formed in the module substrate, and
a cross-sectional area of the first wire is greater than a cross-sectional area of the second wire.

17. The power amplifier circuit according to claim 11, further comprising:
a module substrate that includes multiple layers and on or in which the first power amplifier, the second power amplifier, the third power amplifier, the fourth power amplifier, the transformer, and the first transmission line are disposed, wherein
the first transmission line and the transformer are disposed in different layers of the module substrate.

18. The power amplifier circuit according to claim 17, wherein
the multiple layers include a ground layer in which a planar ground pattern is disposed, and
the ground layer is disposed between a layer in which the transformer is disposed and a layer in which the first transmission line is disposed.

19. A power amplification method comprising:
in a first power mode corresponding to first output power, controlling a first power amplifier, which is connected to an input-side coil of a transformer via a third power amplifier and a fourth power amplifier, to be in an ON state and controlling a second power amplifier, which is connected to the input-side coil of the transformer not via the third power amplifier and the fourth power amplifier, to be in an OFF state; and
in a second power mode corresponding to second output power lower than the first output power, controlling the first power amplifier to be in the OFF state and controlling the second power amplifier to be in the ON state.
